(19) United States
(12) Patent Application Publication
(10) Pub. No.: US 2003/0179803 A1
(43) Pub. Date: Sep. 25, 2003

(54) Vertical cavity surface emitting laser and laser beam transmitting module using the same

(75) Inventor: Misuzu Sagawa, Tokyo (JP)

Correspondence Address: Stanley P. Fisher, Reed Smith LLP, Suite 1400, 3110 Fairview Park Drive, Falls Church, VA, 22042-4503, US

(73) Assignee: Hitachi, Ltd.

(21) Appl. No.: 10/350,034

(22) Filed: Jan. 24, 2003

(30) Foreign Application Priority Data
Mar. 20, 2002 (JP) P2002-077491

(51) Int. Cl. H01S 5/00

(52) U.S. Cl. 372/96

(57) ABSTRACT

A vertical cavity surface emitting laser, useful as a light source in a semiconductor laser module, comprising an InP substrate having an active layer that emits light and a resonator structure having mirrors located above and below the active layer to obtain a laser beam from the light and emit the laser beam substantially perpendicular to the substrate, where at least one of the mirrors is made of AlGaAs/AlGaSb superlattices having an average composition of Al(x)Ga(1-x)AsSb and AlGaAs/AlGaSb superlattices having an average composition of Al(y)Ga(1-y)AsSb (0≦x<y≦1).

### BACKGROUND OF THE INVENTION

1. Field of the Invention

The present invention relates to a structure of a vertical cavity surface emitting laser that emits light vertically to a substrate, and more particularly to a low cost light source in optical communications systems and optical information systems such as LANs and Datacoms.

2. Description of the Related Art

A vertical cavity surface emitting laser that oscillates at 1.3 μm and 1.55 μm is now required as a light source for optical transmission systems. To achieve the vertical cavity surface emitting laser having excellent device characteristics, a high quality active layer and mirrors need to be formed simultaneously.

Mainly a band gap of a gain medium in an active layer determines an oscillation wavelength of a semiconductor laser. InGaAs(P) and InAlGaAs lattice-matched to an InP substrate are generally used for obtaining a long wavelength laser beam. These materials are widely used in active layers of the vertical cavity surface emitting lasers because crystals with high quality crystallinity can be obtained using these materials.

Since the vertical cavity surface emitting laser emits a laser beam vertically to a semiconductor substrate, mirrors of the resonator need to be formed vertically to the laser beam, namely horizontally to the semiconductor substrate. The mirrors are formed by epitaxially growing several to several dozen pairs of two types of thin layers whose refractive indexes are different from each other. The thickness of each layer is λ/4 optical thickness. Such mirrors are called DBR (Distributed Bragg Reflector) mirrors.

On the other hand, since a volume of the active layer, the gain region, is smaller than that of an edge emitting semiconductor laser, the mirrors of the laser resonator need a high reflectivity of over 99%. For example, as the conventional mirror, there is a DBR mirror formed of Al(x)Ga(1-x)As and Al(y)Ga(1-y)As (0≦x<y≦1) lattice-matched to a GaAs substrate. This AlGaAs material system, of which a reflector having highly quality crystallinity and a high reflectivity can be easily formed, is widely used in vertical cavity surface emitting lasers of 0.8 μm bands. Therefore, techniques of forming an active layer that oscillates at a long wavelength band on the GaAs substrate has been investigated. GaInNAs, GaAsSb, quantum dots of InGaAs, and highly-strained InGaAs with a high ratio of In are the examples. However, in these materials, crystals with highly-qualified crystallinity cannot be produced. Thus, the materials are not in practical use.

DBR mirrors on the InP substrate, on which an active layer with high crystallinity can be formed, has been investigated. A vertical cavity surface emitting laser on the InP substrate reported in IEEE Photonics Technology Letters, Vol. 7, pp. 608-610, 1995 uses a combination of semiconductor films of InGaAsP and InP as the mirrors. The refractive index difference between these two semiconductors is so small that forty five pairs of the semiconductors, namely ninety layers, need to be epitaxially grown to obtain a reflectivity of over 99%. Such crystal growth requires a long growth time, decreasing the crystallinity and the uniformity and controllability of the film thickness. Additionally, the laser beam penetrated the mirror so deeply that scattering loss of the mirror might degrade the device characteristics. Further, in such a combination, it was difficult to adjust the wavelength band where high reflectivity could be obtained, namely the stop band, to a wavelength of the gain region because the stop band was narrow. This meant not only that the device yield ratio decreased, but also that the wavelength of the gain region did not match to the stopband when the device was driven without a temperature control and thereby the device could not operate.

On the other hand, in IEEE Journal On Selected Topics In Quantum Electronics, vol. 6, pp.1244-1253, 2000, it has been reported that calculations show that the characteristics of AlGaAsSb mirrors on the InP substrate can be equal to those of AlGaAs mirrors on the GaAs substrate. In addition, a vertical cavity surface emitting laser using the AlGaAsSb mirrors has been reported by the University of California, whose presentation number was ThCl, at Int'l Semiconductor Laser Conference 2000.

However, as described below, since it was extremely difficult to produce high quality crystals using the AlGaAsSb materials, the high quality and high reflectivity mirrors could not be produced. The crystallinity of the active layer that is grown on the mirror also degraded. Thus, the device characteristics and reliability deteriorated.

The difficulty of growing high quality crystals using AlGaAsSb materials is described below. In a quaternary alloy of GaAlAsSb and ternary alloys of GaAsSb and AlAsSb, the elements do not mix evenly and thereby crystals of different compositions are formed when the composition ratio is at a given ratio. This is called a compositional segregation. The region of ratios at which the compositional segregation occurs is called an immiscibility region. The calculation result of the immiscibility region of the AlGaAsSb quaternary alloy has been reported in Japan Journal of Applied Physics, vol. 21, p. 797, 1982.

FIG. 3 shows the calculation result. The horizontal axis indicates ratios of an alloy of Al and Ga, the compositions of group III elements. At the far left side, the alloy ratio of Al is 1.0, indicating that the group III elemental composition consists of only Al. At the far right side, the group III elemental composition consists of only Ga. Between the ends, the compositions of both elements are indicated. For example, at the point of 40% from the left end, the composition of Al and Ga is 60:40. The vertical axis indicates the group V element compositions. At the bottom, the alloy ratio of Sb is 1.0, indicating that the group V elemental composition consists of only Sb. At the top, the alloy ratio of As is 1.0, indicating that the group V elemental composition consists of only As.

The compositional elements inside the circles or partial circles of FIG. 3 segregate because of the immiscibility. To achieve an alloy having high crystallinity, compositions outside the circles are required. The numbers attached to the circles indicate temperatures. The circles indicate the immiscibility regions at the temperatures. Once formed, an alloy keeps its formed condition stably. Therefore, a high-quality alloy can be formed using compositions outside the immiscibility region at temperatures at which the alloy is formed.

To produce a device, an alloy needs to be lattice-matched to a semiconductor substrate. FIG. 3 shows compositions lattice-matched to a InP substrate. The compositions on the lines of the circles need to be used in producing the device on the substrate. The crystal growth temperature of the compositions needs to be at least equal to or over 800 degrees Celsius to prevent the compositional segregation. On the other hand, desorption of group V elements such as P and As occurs in the crystal when the crystal grows at over 800 degrees Celsius and, therefore, a high quality crystal cannot be obtained. When the crystal grows at temperatures between 500 and 700 degrees Celsius to prevent the desorption, the crystal is formed inside the immiscibility region. The elements do not mix evenly inside the immiscibility region so that the composition segregates. A strain and the like caused by the lattice constant difference between the alloy and the substrate result in the crystal deterioration. A high reflectivity mirror cannot be formed because of the crystal deterioration. Further, the crystallinity of an active layer growing on the deteriorated crystal also deteriorates. As described above, with the conventional AlGaAsSb alloy, the semiconductor mirror having high quality crystallinity could not be produced.

### SUMMARY OF THE INVENTION

The present invention provides a vertical cavity surface emitting laser having on its InP substrate a high quality active layer and high quality mirrors with high reflectivity.

In a vertical cavity surface emitting laser having on its InP substrate an active layer that emits light and a resonator structure where mirrors located above and below the active layer to obtain a laser beam from the light, and emitting the laser beam perpendicularly to the plane of the substrate. At least one of the mirrors of the vertical cavity surface emitting laser of the present invention comprises an AlGaAs/AlGaSb superlattice having an average composition of Al(x)Ga(1-x)AsSb and an AlGaAs/AlGaSb superlattice having an average composition of Al(y)Ga(1-y)AsSb (0≦x<y≦1). Additionally, a waveguide is formed by etching around the active region until the bottom of the waveguide extends to the substrate. The waveguide groove is then filled with semiconductor material. Remarkable efficiency is shown when the cavity extends to the substrate. Further, the present invention comprises a semiconductor laser module using the above-described vertical cavity surface emitting laser.

Effects of the invention will be described in the following.

AlGaAsSb lattice-matched to the InP substrate at a usual crystal growth temperature is inside the immiscibility region where it is difficult to form the high quality alloy using AlGaAsSb. On the other hand, as shown in FIG. 3, AlGaAs and AlGaSb are outside the immiscibility region even at 400 degrees Celsius, far lower than the usual crystal growth temperature, so that the high quality crystal using AlGaAs and AlGaSb can be obtained.

On the other hand, it is known that a refractive index of the laser beam is equal to that of an average composition of a layer formed by epitaxialy growing alternative layers sufficiently thinner than a wavelength of the laser beam. For example, a layer having nearly the optical equivalence to an AlGaAsSb quaternary alloy can be obtained by epitaxialy growing thin layers of AlGaAs and AlGaSb alternatively. FIGS. 2A and 2B show a case when this fact is applied to an AlGaAsSb mirror. FIG. 2A shows a conventional structure of the mirror formed of an AlAsSb/GaAsSb alloy. A mirror having high crystallinity cannot be obtained using this structure because of the above described influence of the immiscibility. In a preferred structure of the invention shown in FIG. 2B, the AlAsSb layer consists of a combination of thin films of AlAs and AlSb, and the GaAsSb layer consists of a combination of thin films of GaAs and GaSb. In the process of forming superlattices, the film thickness ratio between AlAs and AlSb or GaAs and GaSb is adjusted so that the average lattice constant of these layers are lattice-matched to the InP substrate. As a result, for the laser beam, the superlattices are just like an AlGaAsSb alloy on the InP substrate. Due to the structure of the invention, an AlGaAsSb superlattice mirror having high quality crystallinity at a usual growth temperatures in the range of 500 to 600 degrees Celsius can be obtained. FIG. 2B shows the superlattice whose average composition is a ternary composition of AlGaAs and GaAsSb. The immiscibility region of FIG. 3 shows that a superlattice consisting of thin films of AlGaAs and AlGaSb, whose average composition is AlGaSb, also exhibits the above-described effect.

Further, by properly designing the film thickness of AlGaSb and AlGaAs, the average composition of the superlattice provides a larger band gap than that of the AlGaAsSb alloy due to a quantum effect. When the mirror consists of a layer having a band gap smaller than a wavelength of a laser beam, the layer absorbs the light, causing negative influence to the laser characteristics. The superlattice mirror has a larger band gap than the alloy, and thus absorbs less laser beam than the AlGaAsSb alloy would absorb. The structure using the superlattice consisting of AlGaAs and AlGaSb is meaningful because, generally, the smaller number of elements that form an alloy, the easier the crystal growth and a crystal film is produced with high-quality crystallinity. As described above, a preferred semiconductor mirror of the present invention is formed of superlattices, not alloys.

### BRIEF DESCRIPTION OF THE DRAWINGS

For the present invention to be clearly understood and readily practiced, the present invention will be described in conjunction with the following figures, wherein like reference characters designate the same or similar elements, which figures are incorporated into and constitute a part of the specification, wherein:

FIG. 1 shows a vertical cavity surface emitting laser structure according to a preferred Embodiment of the present invention;

FIG. 2A shows a band gap structure of a conventional mirror;

FIG. 2B shows a band gap structure of a mirror of a preferred embodiment of the present invention;

FIG. 3 shows the immiscibility region;

FIG. 4 shows another preferred vertical cavity surface emitting laser of the present invention; and

FIG. 5 shows a preferred module using the vertical cavity surface emitting laser of the present invention.

### DETAILED DESCRIPTION OF THE INVENTION

It is to be understood that the figures and descriptions of the present invention have been simplified to illustrate elements that are relevant for a clear understanding of the present invention, while eliminating, for purposes of clarity, other elements that may be well known. Those of ordinary skill in the art will recognize that other elements are desirable and/or required in order to implement the present invention. However, because such elements are well known in the art, and because they do not facilitate a better understanding of the present invention, a discussion of such elements is not provided herein. The detailed description of the present invention and the preferred embodiment(s) thereof is set forth in detail below with reference to the attached drawings.

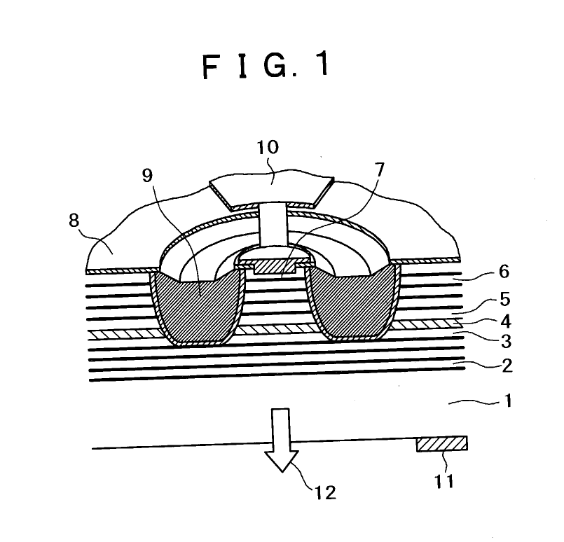

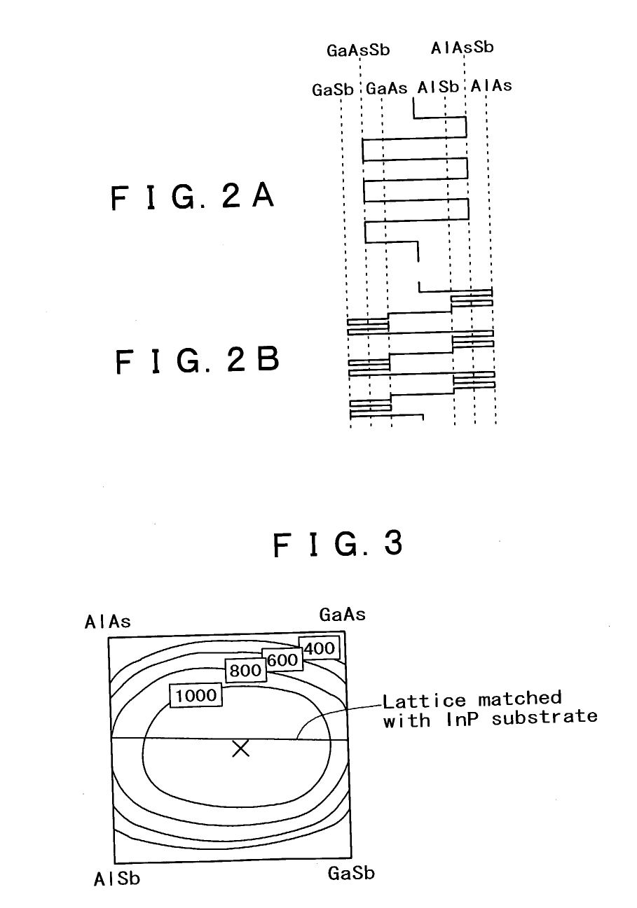

Preferred embodiments of the invention are described below with reference to the FIGS. 1, 3, 4, and 5.

### Embodiment 1

A first preferred embodiment of the invention is described with reference to FIG. 1. This preferred embodiment shows a vertical cavity surface emitting laser that oscillates at a wavelength of 1.55 μm band for a light source for Datacoms and LANs. FIG. 1 is a cross-sectional perspective view.

Illustrated in FIG. 1, reference numerals 2 and 6 are semiconductor multilayer mirrors formed of superlattices. These mirrors are formed by epitaxialy growing low refractive index layers and high refractive index layers alternatively. The thickness of each layer is ¼ wavelength in the semiconductor. The low refractive index layer is formed of a superlattice made of thin films of AlAs and AlSb. The average lattice constant of the low refractive index layer is assigned to that of an InP substrate so that the layer is lattice-matched to the substrate. The high refractive index layer is formed of a superlattice made of thin films of GaAs and GaSb. The average lattice constant of the high refractive index layer is assigned to that of the InP substrate so that the layer is lattice-matched to the substrate.

FIG. 1 shows an n-type substrate 1, an n-type superlattice semiconductor multilayer mirror 2 formed by epitaxialy growing alternatively superlattice layers having an average composition of GaAsSb and superlattice layers having an average composition of AlAsSb, an n-type InP spacer layer 3, an active layer 4 formed of an undoped InGaAs strained quantum well layer and an undoped InGaAsP barrier layer, a p-type InP spacer layer 5, a p-type superlattice semiconductor multilayer mirror 6 formed by epitaxialy growing alternatively superlattice layers having an average composition of GaAsSb and superlattice layers having an average composition of AlAsSb, a p-type InGaAs contact layer 7, an insulating film 8, polyimide 9, a positive electrode 10, negative electrode 11, and output laser beam 12.

A preferred method of fabricating the vertical cavity surface emitting laser of this preferred embodiment is described below. With a MBE (Molecular Beam Epitaxy) method, the superlattice semiconductor multilayer mirror 2, the n-type InP spacer layer 3, the active layer 4, the p-type InP spacer layer 5, the superlattice semiconductor multilayer mirror 6, and the p-type InGaAs contact layer 7 are formed on the n-type substrate 1. Next, with a photolithography and etching method, a circle shaped mesa structure is formed. With a thermal or plasma CVD (Chemical Vapor Deposition) method, the insulating film 8 is formed, and then, with a coating and an etchback method, the polyimide 9 is formed. Lastly, the positive electrode 10 and the negative electrode 11 are formed.

The invention embodies a high quality and high reflectivity mirror on an InP substrate, on which a high quality active layer can be achieved. The vertical cavity surface emitting laser of the present invention has lasing wavelengths of 1.3 and 1.55 μm bands and can be used for light emitting systems.

The vertical cavity surface emitting laser of this first preferred embodiment of the present invention operated continuously at room temperature. The threshold current was about 100 μA. The laser beam was emitted through the substrate. The lasing wavelength at room temperature was 1.55 μm and the laser had a long life of over one hundred thousand hours.

### Embodiment 2

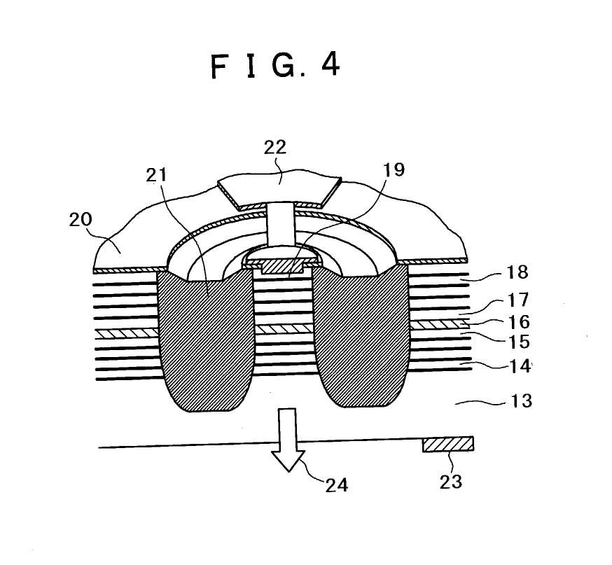

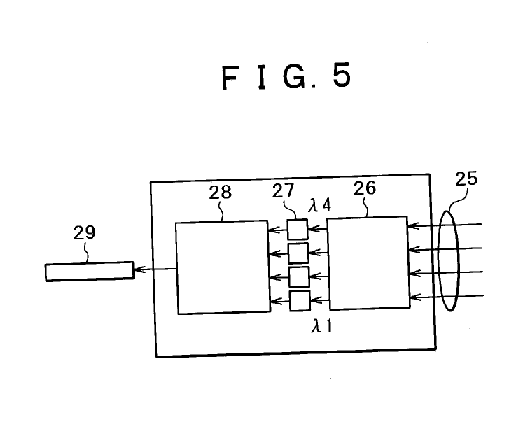

A second preferred embodiment of the present invention is described below with reference to FIGS. 4 and 5. This preferred embodiment shows a vertical cavity surface emitting laser with a wavelength of 1.3 μm band, intended for a light source for the optical transmission systems.

FIG. 4 is a cross-sectional perspective view. FIG. 5 shows a module incorporating the vertical cavity surface emitting laser of this second preferred embodiment.

In FIG. 4, reference numerals 14 and 18 refer to semiconductor multilayer mirrors formed of superlattices. These mirrors are formed by epitaxialy growing low refractive index layers and high refractive index layers alternatively. The thickness of each layer is ¼ wavelength in the semiconductor. The low refractive index layer is formed of thin films of AlAs and AlSb. The average lattice constant of the low refractive index layer is assigned to that of the InP substrate so that the layer is lattice-matched to the substrate. The high refractive index layer is formed of thin films of AlGaAs and AlGaSb. The average lattice constant of the high refractive index layer is adjusted to that of the InP substrate so that the layer is lattice-matched to the substrate. The composition ratio between Al and Ga, group III elements, is 5:95.

The cavity forming the mesa is buried with InP so that heat of the active layer is easily dissipated. Since a binary alloy has generally a higher heat conductivity than a ternary alloy, the structure where the InP buried layer reaches the InP substrate is efficient for heat dissipation.

FIG. 4 shows an n-type InP substrate 13, a superlattice semiconductor multilayer mirror 14 formed by epitaxialy growing superlattice layers having an average composition of AlGaAsSb and superlattice layers having an average composition of AlAsSb alternatively, an n-type InP spacer layer 15, an active layer 16 formed of an undoped InGaAs strained quantum well layer and an undoped InAlGaAs barrier layer, a p-type InP spacer layer 17, a superlattice semiconductor multilayer mirror 18 formed by epitaxialy growing superlattice layers having an average composition of AlGaAsSb and superlattice layers having an average composition of AlAsSb alternatively, a p-type InGaAs contact layer 19, an insulating film 20, an insulating InP buried layer 21, a positive electrode 22, a negative electrode 23, and an output laser beam 24.

A preferred method of fabricating the vertical cavity surface emitting laser of this second preferred embodiment is described below. With an MBE method, a superlattice semiconductor multilayer mirror 14, an n-type InP spacer layer 15, an active layer 16, a p-type InP spacer layer 17, a superlattice semiconductor multilayer mirror 18, and a p-type InGaAs contact layer 19 are formed on the n-type InP substrate 13. Next, with a thermal or plasma CVD method, a SiO2 or SiNx film is formed as a mask for a mesa and a selective crystal growth, and a circle shaped pattern is formed on the film with a photolithography and etching method. The circle shaped mesa is formed using the insulating film as the mesa mask, as shown in FIG. 4. With an MOVPE (Metalorganic Vapor Phase Epitaxy) method, the insulating InP buried layer 21 is formed using the insulating film as the selective growth mask. Then that insulating mask is removed by etching. With the CVD method, the insulating film 20 is formed. Lastly, the positive electrode 22 and the negative electrode 23 are formed.

The vertical cavity surface emitting laser of this second preferred embodiment operated continuously at room temperature. The threshold current was about 100 μA. The laser beam was emitted through the substrate. The lasing wavelength was 1.3 μm and the laser had a Long life of over one hundred thousand hours.

Next, a preferred CWDM (Coarse Wavelength Division Multiplexing) light source module for LANs of the present invention is described as one example of a use of the vertical cavity surface emitting laser in a module. FIG. 5 shows a preferred structure of such a module. A laser driver 26 translates input electrical signals 25 to laser driving signals that drive the vertical cavity surface emitting lasers 27 of the present invention. A multiplexer 28 multiplexes light signals emitted from the lasers 27. The multiplexed signals output through an output optical fiber 29 which is a single mode fiber. The lasers operate without a temperature control such as e.g., a Peltier element. Wavelengths of the lasers λ1 to λ4 are 1276, 1300, 1325, and 1350 nm, respectively. The lasers operated at 3.125 GBd for a light transmission of 2 km. There was no crosstalk between signals of the wavelengths, realizing a code error ratio of under 10E-12.

The foregoing invention has been described in terms of preferred embodiments. However, those skilled, in the art will recognize that many variations of such embodiments exist. Such variations are intended to be within the scope of the present invention and the appended claims.

Nothing in the above description is meant to limit the present invention to any specific materials, geometry, or orientation of elements. Many part/orientation substitutions are contemplated within the scope of the present invention and will be apparent to those skilled in the art. The embodiments described herein were presented by way of example only and should not be used to limit the scope of the invention.

Although the invention has been described in terms of particular embodiments in an application, one of ordinary skill in the art, in light of the teachings herein, can generate additional embodiments and modifications without departing from the spirit of, or exceeding the scope of, the claimed invention. Accordingly, it is understood that the drawings and the descriptions herein are proffered by way of example only to facilitate comprehension of the invention and should not be construed to limit the scope thereof.

What is claimed is:

1. A vertical cavity surface emitting laser comprising an InP substrate having an active layer that emits light and a resonator structure comprising mirrors located above and below the active layer to obtain a laser beam from the light and emit the laser beam substantially perpendicular to the substrate,
wherein at least one of the mirrors comprises AlGaAs/AlGaSb superlattices having an average composition of Al(x)Ga(1-x)AsSb and AlGaAs/AlGaSb superlattices having an average composition of Al(y)Ga(1-y)AsSb (0<x<y<1).

2. A vertical cavity surface emitting laser comprising an InP substrate having an active layer that emits light and a resonator structure comprising mirrors located above and below the active layer to obtain a laser beam from the light and emit the laser beam substantially perpendicular to the substrate,
wherein at least one of the mirrors comprises GaAs/GaSb superlattices having an average composition of GaAsSb or AlAs/AlSb superlattices having an average composition of AlAsSb.

3. The vertical cavity surface emitting laser according to claim 1 wherein a wavelength of said laser beam is in the range of 1.2 μm to 1.6 μm.

4. The vertical cavity surface emitting laser according to claim 2 wherein a wavelength of said laser beam is in the range of 1.2 μm to 1.6 μm.

5. The vertical cavity surface emitting laser according to claim 1 wherein a groove is formed around said active layer.

6. The vertical cavity surface emitting laser according to claim 5 wherein said groove is formed by etching and wherein said groove extends to said substrate and is filled with a semiconductor material.

7. The vertical cavity surface emitting laser according to claim 5 wherein a waveguide comprises said groove.

8. The vertical cavity surface emitting laser according to claim 2 wherein a groove is formed around said active layer.

9. The vertical cavity surface emitting laser according to claim 8 wherein said groove is formed by etching and wherein said groove extends to said substrate and is filled with a semiconductor material.

10. The vertical cavity surface emitting laser according to claim 9 wherein a waveguide comprises said groove.

11. The vertical cavity surface emitting laser according to claim 3 wherein a groove is formed around said active layer.

12. The vertical cavity surface emitting laser according to claim 11 wherein said groove is formed by etching and wherein said groove extends to said substrate and is filled with a semiconductor material.

13. The vertical cavity surface emitting laser according to claim 11 wherein a waveguide comprises said groove.

14. A semiconductor laser module having as a light source a vertical cavity surface emitting laser comprising an InP substrate having an active layer that emits light and a resonator structure comprising mirrors located above and below the active layer to obtain a laser beam from the light and emit the laser beam substantially perpendicular to the substrate, wherein at least one of the mirrors comprises AlGaAs/AlGaSb superlattices having an average composition of Al(x)Ga(1-x)AsSb and AlGaAs/AlGaSb superlattices having an average composition of Al(y)Ga(1-y)AsSb (0<x<y<1).

15. The semiconductor laser module of claim 14 wherein a wavelength of said laser beam is in the range of 1.2 μm to 1.6 μm.

16. The semiconductor laser module of claim 14 wherein a groove is formed around said active layer.

17. The semiconductor laser module of claim 16 wherein said groove is formed by etching and wherein said groove extends to said substrate and is filled with a semiconductor material.
